(19) United States
(12) Patent Application Publication
(10) Pub. No.: US 2007/0033800 A1
(43) Pub. Date: Feb. 15, 2007

(54) Method for electrically contacting a component to a flat cable

(75) Inventor: Gerd Bierbaum, Oberboihingen (DE)

Correspondence Address: FITCH, EVEN, TABIN & FLANNERY, P. O. BOX 18415, WASHINGTON, DC, 20036, US

(73) Assignee: DaimlerChrysler AG Epplestrasse 225, Stuttgart (DE)

(21) Appl. No.: 10/546,276

(22) PCT Filed: Dec. 20, 2003
(86) PCT No.: PCT/EP03/14683

§ 371 Date: Oct. 12, 2006

(30) Foreign Application Priority Data
Feb. 25, 2003 (DE) 103 07 846.0

(51) Int. Cl. H05K 3/30

(52) U.S. Cl. 29/832; 29/854

(57) ABSTRACT

A method for electrically contacting an electrical component (5a) to at least one conductor track (4) of a flat cable (1) with the following method steps:
a) The insulating layer (2) of the flat cable (1) is removed from a conductor section (6) of the conductor track (4).
b) The stripped conductor section (6) is severed to form two separate sub-sections (10a, 10b).
c) The component (5a) is positioned on a contact segment (11a, 11b) of at least one sub-section (10a, 10b).
d) The component (5a) is electrically contacted to the contact segments (11a, 11b) of the sub-sections (10a, 10b).

The invention relates to a method for electrically connecting an electrical or electronic component to at least one conductor track of a flat cable. Flat cables are known in particular as FFCs (=Flexible Flat Cables) or as flexible printed circuits. Flexible flat cables usually have a number of flat-rolled copper wires or copper strips running next to one another in parallel as current conductors, which are fixed on an insulating material and are sheathed by this insulating material. This insulation takes place for example by means of a laminating or extruding operation. It is known from DE 100 19 410 A1. to electrically contact the electrical conductor tracks of the flat cable to an SMD component.

The invention is based on the object of proposing a particularly simple method for the electrical contacting of a component to at least one conductor track of a flat cable.

This object is achieved by the combination of features of claim 1.

According to the invention, firstly the insulating layer of the flat cable is removed from a conductor section of a conductor track to be contacted to the electrical or electronic component. The stripped conductor section is then severed to form two separate sub-sections. This separation takes place for example by cutting or punching. During the severing of the conductor section, a segment of the conductor track material is preferably also removed. For the later electrical contacting of the component to the two sub-sections, the component is positioned on a contact segment of at least one sub-section. After that, the component can be electrically contacted at least to the contact segment on which it has been positioned. In a further method step, the component is likewise electrically contacted to the contact segment of the second sub-section.

On account of the separation of the stripped conductor section into two sub-sections, the component acts in its final assembled state to a certain extent as an electrical bridge between the two sub-sections. By a multiplicity of such bridges with corresponding components, entire electrical or electronic circuits can be advantageously realized, as in the case of conventional circuits on printed circuit boards. With the invention, it is then possible to dispense with such printed circuit boards. Rather, the components are directly connected to the flat cable. The preparation of the flat cable for the positioning or placement of the components, the positioning itself and the electrical contacting of the components to the flat cable can be produced in few working steps fully automatically and, on account of a reduced number of parts, inexpensively and reliably in terms of the process. Furthermore, dispensing with printed circuit boards has environmentally friendly effects. The recycling of electronic scrap is simplified. The removal of the insulating layer of the flat cable from the selected conductor section may be performed for example mechanically by means of a suitable tool. The stripping of the insulation is preferably performed by means of a laser.

For certain components, it is adequate to strip the insulation from the flat cable in the region of the selected conductor section on one side, i.e. only on one flat side of the flat cable.

The measure according to claim 3 takes account of components which are to be electrically contacted on different flat sides of the two sub-sections.

The measures of claims 4 to 9 take account of the different geometrical dimensions and physical properties of different components. Bends of the sub-sections that are adapted to the respective component allow components which, for example, have a greater width and/or greater length than the stripped conductor section also to be integrated on the flat cable.

Claims 10 to 16 support reliable electrical contacting between the component and the contact segments. The electrical connecting means may be provided on the contact segments and/or on the component. A tin-plating is provided, for example, for this purpose. Soldering tin is preferably applied to at least one contact segment and/or at least one electrical contact point of the component (claim 16). The soldering tin may be applied in the form of soldering paste by means of a dispenser or else by the screen printing process. After providing the electrical connecting means and the positioning of the component, an electrical connection takes place between the component and the respective contact segment. This electrical connection takes effect, for example, by soldering, preferably by a selective soldering process, such as iron, laser or light soldering, on the contact segments. As an alternative to a soldering process, connecting processes such as welding or adhesive bonding by means of electrically conductive adhesive may also be used—depending on the component used.

The measure according to claim 17 supports positioning of components on the flat cable that is reliable in terms of the process.

The invention is explained in more detail on the basis of the exemplary embodiments that are represented in the drawings, in which:

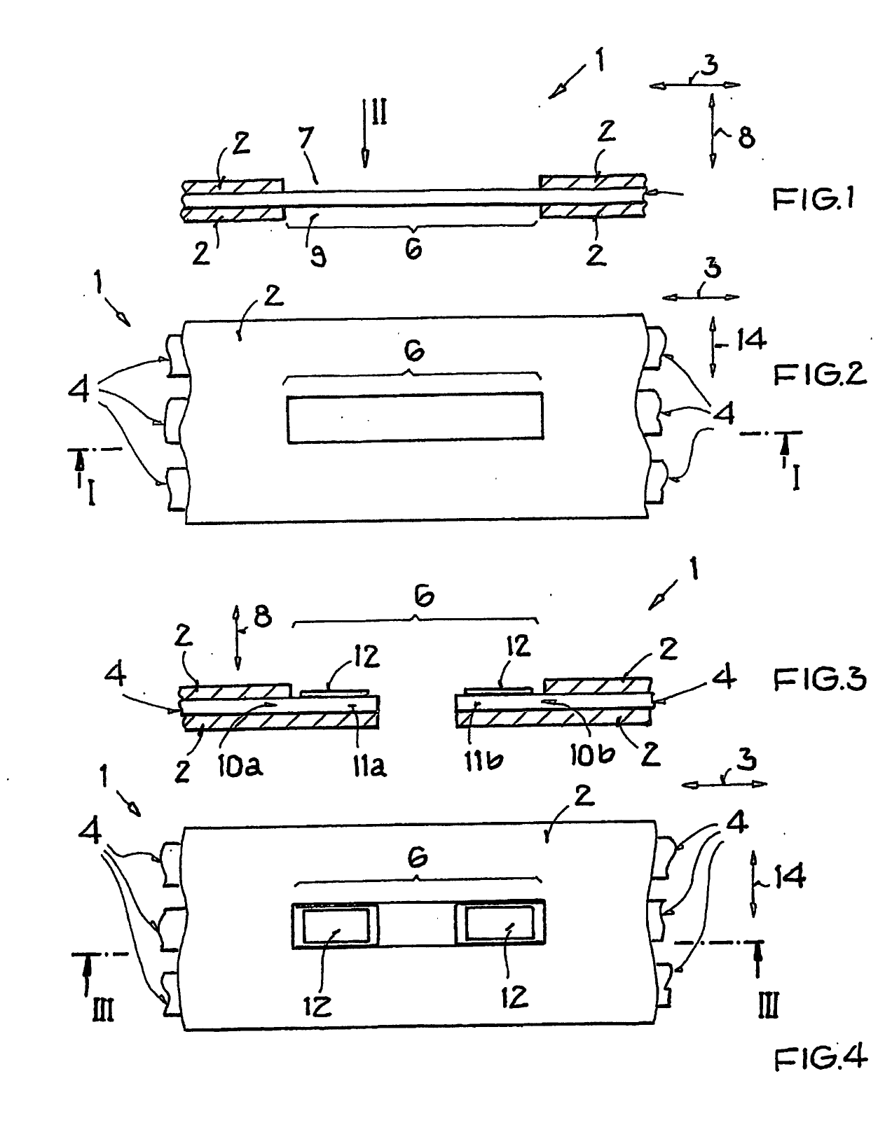

FIG. 1 shows a stripped conductor section of a flat cable corresponding to sectional line I-I in FIG. 2,

FIG. 2 shows a plan view of the flat cable according to the viewing direction II in FIG. 1,

FIG. 3 shows a severed conductor section of a flat cable corresponding to sectional line III-III in FIG. 4,

FIG. 4 shows a plan view of the flat cable according to the viewing direction IV in FIG. 3,

FIG. 5 shows the severed conductor section according to FIG. 3 with a positioned component,

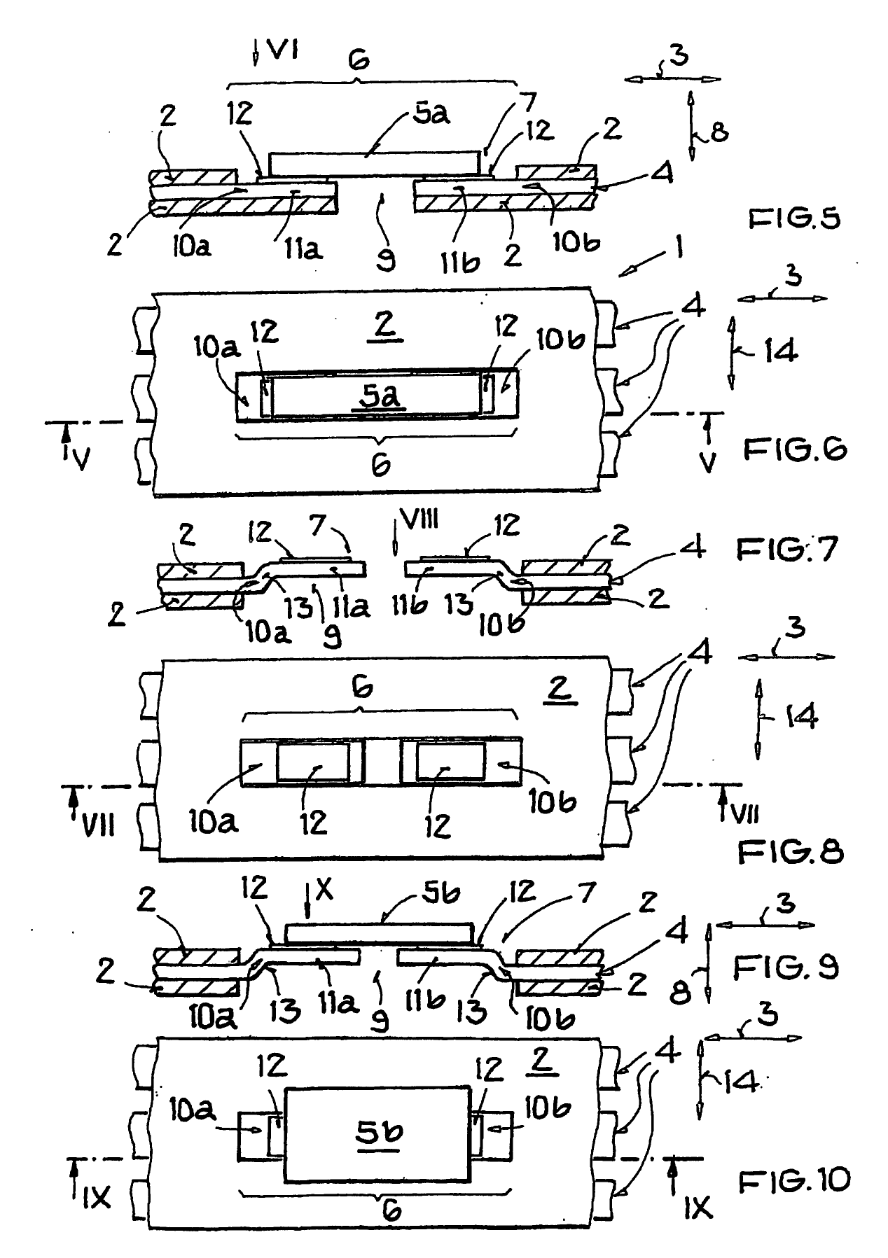

FIG. 6 shows a plan view of the flat cable according to viewing direction VI in FIG. 5,

FIGS. 7-10 show a further embodiment of the severed conductor section with bent sub-sections and a positioned component,

FIGS. 11-16 show a further embodiment of the severed conductor section with bent sub-sections and a component positioned on it,

FIG. 17 shows a plan view of the flat cable with components positioned on it according to the embodiment of FIG. 16.

FIG. 1 and FIG. 2 show a flexible flat cable 1 with a pliable insulation 2. This insulation 2 sheaths a total of three conductor tracks 4 arranged in parallel at a distance from one another and running in the longitudinal direction of conduction 3. To electrically connect or contact an electrical or electronic component 5 to a conductor track 4 of the flat cable 1, firstly the insulation 2 of the flat cable 1 is removed from a selected conductor section 6 of the conductor track 4 (FIG. 1). In the case of the embodiments according to FIG. 1 and FIGS. 7-16, the conductor section 6 is thereby stripped on both, opposite flat sides—as viewed in the plane of the page of the drawing, on an upper flat side 7 and a lower flat side 9, opposite from the latter in the vertical direction 8—of the flat cable 1. The length of the conductor section 6 in the longitudinal direction of conduction 3 must be chosen such that the respective component 5 can be positioned on the conductor section 6 without hindrance and that there is still adequate space for the electrical connection of the component 5. After the stripping, conductor track material is removed in a central region of the conductor section 6 (for example by punching). This separation of the conductor section 6 produces two separate sub-sections 10a, 10b (for example FIG. 3). An electrical connecting means 12 is arranged between the contact segments 11a, 11b of the two sub-sections 10a, 10b and the respective component 5.

In the case of the embodiment according to FIG. 3-FIG. 6, the connecting means 12 is provided on both contact segments 11a, 11b. This preferably takes place by applying soldering tin in the form of soldering paste by means of a dispenser. However, soldering adhesive may also be used as the electrical connecting means 12. After providing the electrical connecting means 12 on the two sub-sections 10a, 10b, the component 5a is positioned on the contact segments 11a, 11b, for example by means of an automatic placement machine. After the positioning, electrical connection takes place between the component 5a and both contact segments 11a, 11b. This is preferably performed by a soldering operation, for example a selective soldering process, such as iron, laser or light soldering, in the region of the electrical connecting means 12.

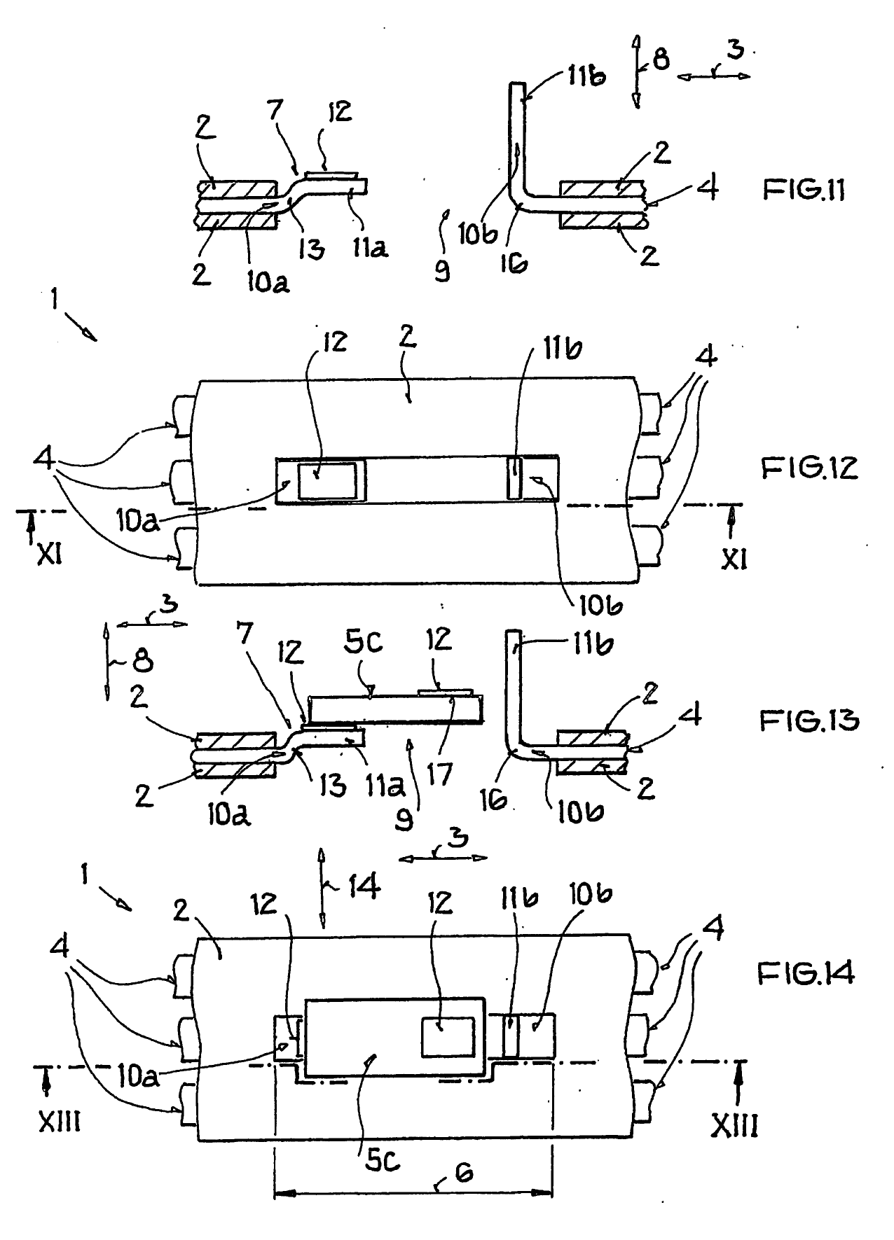

In the case of a second embodiment (FIG. 7-FIG. 10), both sub-sections 10a, 10b are bent in relation to the plane of the associated conductor track 4. To realize this bending, the conductor track 4 is stripped—as in FIG. 1—both on the upper flat side 7 and on the lower flat side 9. Both sub-sections 10a, 10b are bent in a bending region 13 in such a way that their contact segments 11a, 11b are arranged parallel to the plane of the insulation 2. In this case, the contact segments 11a, 11b are arranged approximately flush with the surface of the insulation 2 on the upper flat side 7. This allows components 5 which have a greater dimensioning than the conductor section 6 in the longitudinal direction of conduction 3 and/or in the transverse direction 14 to be positioned and integrated on the flat cable 1 without hindrance. In the exemplary embodiment according to FIG. 10, the component 5b has a greater width in the transverse direction 14 than the conductor section 6. Furthermore, the sub-sections 10a, 10b according to FIG. 7-FIG. 10 are bent in such a way that their contact segments 11a, 11b are arranged in the same plane after the bending operation. As in the case of the embodiment according to FIG. 3-FIG. 6, after the bending operation the electrical connecting means 12 are provided on both contact segments 11a, 11b. Then, the component 5 is positioned on both contact segments 11a, 11b and after that electrically connected to these two contact segments 11a, 11b (FIG. 9, FIG. 10). One of the aforementioned connecting processes is preferably used for this purpose.

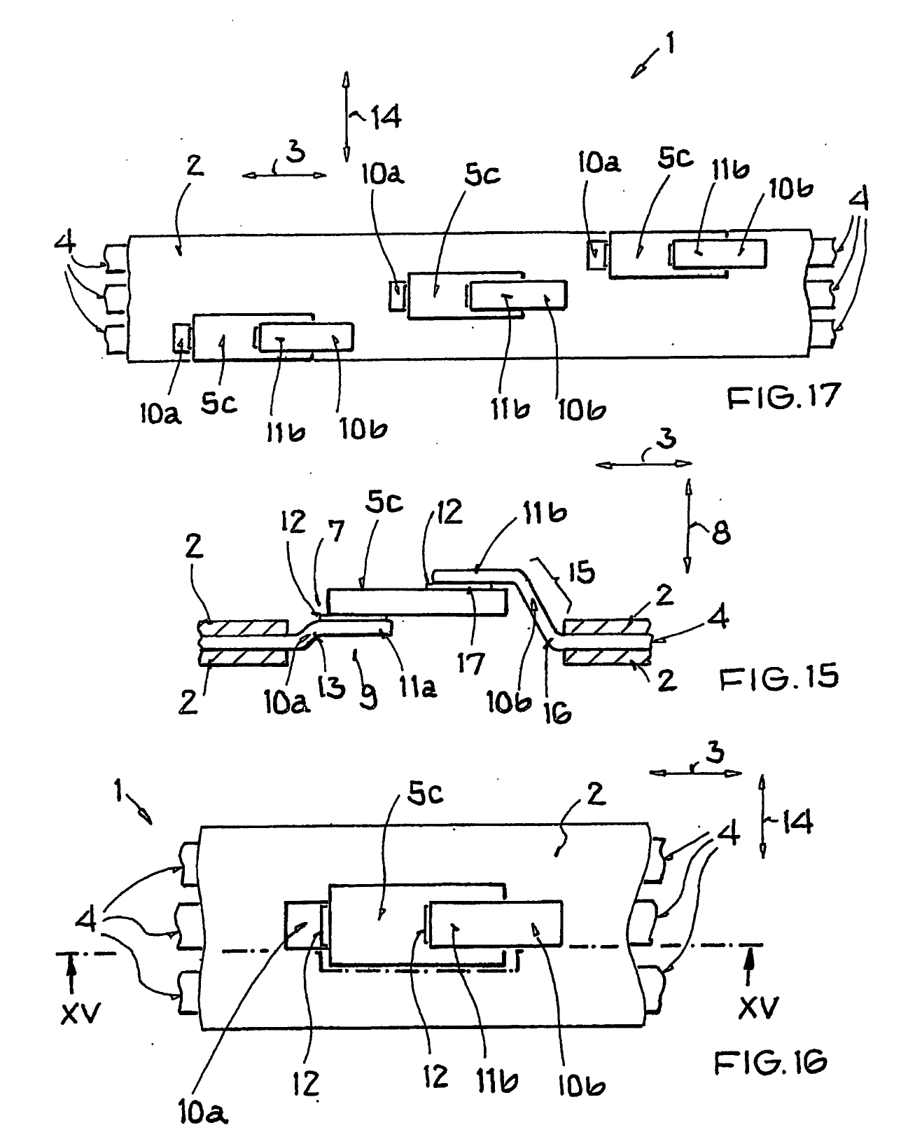

In the case of a further embodiment according to FIG. 11-FIG. 16, the two sub-sections 10a, 10b are bent in such a way that their contact segments 11a, 11b are arranged in different planes after the bending operation (FIG. 15). In order to achieve the bending region 13 of the sub-section 10a and the bending section 15 that are represented in FIG. 15, the length of the conductor section 6 in the longitudinal direction of conduction 3 must be selected appropriately. Once the insulation 2 has been removed both from the upper flat side 7 and from the lower flat side 9 in the region of the conductor section 6, the conductor section 6 is separated into the two sub-sections 10a, 10b (FIG. 11). After that, the sub-section 10a is bent in such a way that its contact segment 11a runs approximately flush with the surface of the insulation 2 on the upper flat side 7. This ensures that the component 5c rests more or less flat on the contact segment 11a and that the electrical connection which then follows can be properly carried out.

In a further method step, the sub-section 10b is bent round. The bend 16 produced as a result is formed in such a way that the region of the contact segment 11b is arranged approximately at right angles to the longitudinal direction of conduction 3 and at right angles to the plane of the flat cable that is defined by the longitudinal direction of conduction 3 and the transverse direction 14 (FIG. 11). After the bending of the sub-section 10b, the electrical connecting means 12 is applied to the surface of the contact segment 11a that is facing the upper flat side 7. As an alternative, the two method steps of bending the contact segment 11b and providing the electrical connecting means 12 on the contact segment 11a may also take place in the reverse sequence. The reverse sequence of the two method steps is advantageous for example if the electrical connecting means (for example soldering paste) is applied by means of screen printing, which may be the case in particular when there are a relatively large number of components 5c to be positioned.

After these two aforementioned method steps, the component 5c is positioned on the contact segment 11a and electrically contacted to this contact segment 11a via the electrical connecting means 12 (FIG. 13). In the case of this embodiment, as a difference from the aforementioned embodiments, the electrical connecting means 12 is not provided on the contact segment 11b. Rather, the electrical connecting means is provided at an electrical contact point 17 of the component 5c corresponding to the contact segment 11b. Then, the bending section 15 of the sub-section 10b is bent in such a way that the contact segment 11b rests more or less flat on the component 5c with the electrical connecting means 12 interposed (FIG. 15). In this case, the two contact segments 11a, 11b are arranged approximately parallel to each other in different planes. Once the sub-section 10b has been bent according to FIG. 15, the contact segment 11b and the electrical contact point 17 of the component 5c can be electrically connected to each other.

It goes without saying that different components 5a, 5b, 5c can be positioned and electrically contacted on a conductor track 4 or else on a number of conductor tracks 4 of the same flat cable 1. They may be arranged at different points in the longitudinal direction of conduction 3. In the case of the section of the flat cable 1 that is represented in FIG. 17, a total of three components 5c are integrated on a respective conductor track 4 of the flat cable 1.

It should be pointed out that the technical details represented in the drawings are not necessarily true to scale.

1. A method for electrically contacting an electrical component (5a, 5b, 5c) to at least one conductor track (4) of a flat cable (1),
the insulating layer (2) of the flat cable (1) being removed from a conductor section (6) of the conductor track (4),
characterized by the following method steps:
after the removal of the insulating layer (2), the stripped conductor section (6) is severed to form two separate sub-sections (10a, 10b),
the component (5a, 5b, 5c) is positioned on a contact segment (11a, 11b) of at least one sub-section (10a, 10b),
the component (5a, 5b, 5c) is electrically contacted to the contact segments (11a, 11b) of the sub-sections (10a, 10b).

2. The method as claimed in claim 1, characterized in that the stripping of the insulation is performed by means of a laser.

3. The method as claimed in claim 1, characterized in that the conductor section (6) is stripped on both, opposite flat sides (7, 9) of the flat cable (1).

4. The method as claimed in claim 1, characterized in that at least one sub-section (10a, 10b) is bent in relation to the plane of the associated conductor track (4).

5. The method as claimed in claim 4, characterized in that the sub-section (10a, 10b) is bent in such a way that its contact segment (11a, 11b) is arranged approximately parallel to the insulating layer (2).

6. The method as claimed in claim 5, characterized in that the contact segment (11a, 11b) is arranged approximately flush with the surface of the insulating layer (2) after the bending operation.

7. The method as claimed in claim 4, characterized in that both sub-sections (10a, 10b) are bent and in that their contact segments (11a, 11b) are arranged in the same plane after the bending operation.

8. The method as claimed in claim 4, characterized in that both sub-sections (10a, 10b) are bent and in that their contact segments (11a, 11b) are arranged in different planes after the bending operation.

9. The method as claimed in claim 4, characterized in that at least one sub-section (10a, 10b) is bent before the positioning of the component (5a, 5b, 5c).

10. The method as claimed in claim 1, characterized in that an electrical connecting means (12) for the electrical contacting is arranged between the contact segments (11a, 11b) of the two sub-sections (10a, 10b) and the component (5a, 5b, 5c).

11. The method as claimed in claim 10, characterized in that the connecting means (12) is provided on the contact segment (11a, 11b) of at least one sub-section (10a, 10b).

12. The method as claimed in claim 10, characterized in that the connecting means (12) is provided on the contact segment (11a, 11b) of the sub-section (10a, 10b) after the bending of the latter.

13. The method as claimed in claim 10, characterized in that the connecting means (12) is provided on the contact segment (11a) of a single sub-section (10a).

14. The method as claimed in claim 10, characterized in that the component (5a, 5b, 5c) is positioned on the contact segment (11a, 11b) of a sub-section (10a, 10b) after the connecting means (12) has been provided on this contact segment (11a, 11b).

15. The method as claimed in claim 10, characterized in that the connecting means (12) is provided at least one electrical contact point (17) of the component (5c) corresponding to a contact segment (11b).

16. The method as claimed in claim 10, characterized by soldering tin as the connecting means (12).

17. The method as claimed in claim 1, characterized in that the component (5a, 5b, 5c) is positioned by means of an automatic placement machine.
